(19) United States
(12) Patent Application Publication
(10) Pub. No.: US 2007/0249175 A1
(43) Pub. Date: Oct. 25, 2007

(54) Pitch-shrinking technologies for lithographic application

(76) Inventor: Yijian Chen, Albany, CA (US)

Correspondence Address: Yijian Chen, 1049 Talbot Avenue, Albany, CA, 94706, US

(21) Appl. No.: 11/407,174

(22) Filed: Apr. 20, 2006

(51) Int. Cl. H01L 21/302

(52) U.S. Cl. 438/717; 257/E21.232

(57) ABSTRACT

Two pitch-shrinking technologies are invented, which allow us to further reduce the pitch size significantly smaller than the minimum feature size resolvable with any conventional lithographic technology. One technology can be used to shrink the pitch size of both line/space (straight or wiggling) and contact-hole patterns by half from the initial (minimum) pitch size resolvable with a conventional lithography, and the other technology can reduce the pitch size of a line/space pattern down to one third of the initial pitch size resolvable with a conventional lithography. These two technologies provide production worthy methods for the whole semiconductor industry to continue the functional device scaling beyond the resolution limit of the conventional lithography.

The semiconductor industry is entering a critical stage where optical DUV (deep ultraviolet) lithography technology appears to approach its limit with increasing difficulties in sustaining functional device scaling. Optical DUV immersion lithography with high-index fluid has the capability of printing features down to 35 nm. The potential next-generation lithography (NGL) technologies include EUV (extreme ultraviolet), maskless, and nano-imprint lithography [1]. However, all these NGL technologies face their own technological challenges and still need a long development time before they can be applied to high-throughput manufacturing.

Two pitch-shrinking technologies are invented which allow us to significantly reduce the minimum pitch size resolvable with any conventional lithographic technology. One technology can be used to shrink the pitch size of both line/space and contact-hole patterns by half from the initial pitch size resolvable with a conventional lithography, and the other can reduce the pitch size of line/space patterns (straight or wiggling) down to one third of the initial pitch size resolvable with a conventional lithography. They provide production worthy methods for the whole semiconductor industry to continue device scaling to sub-35 nm node with no need of NGL.

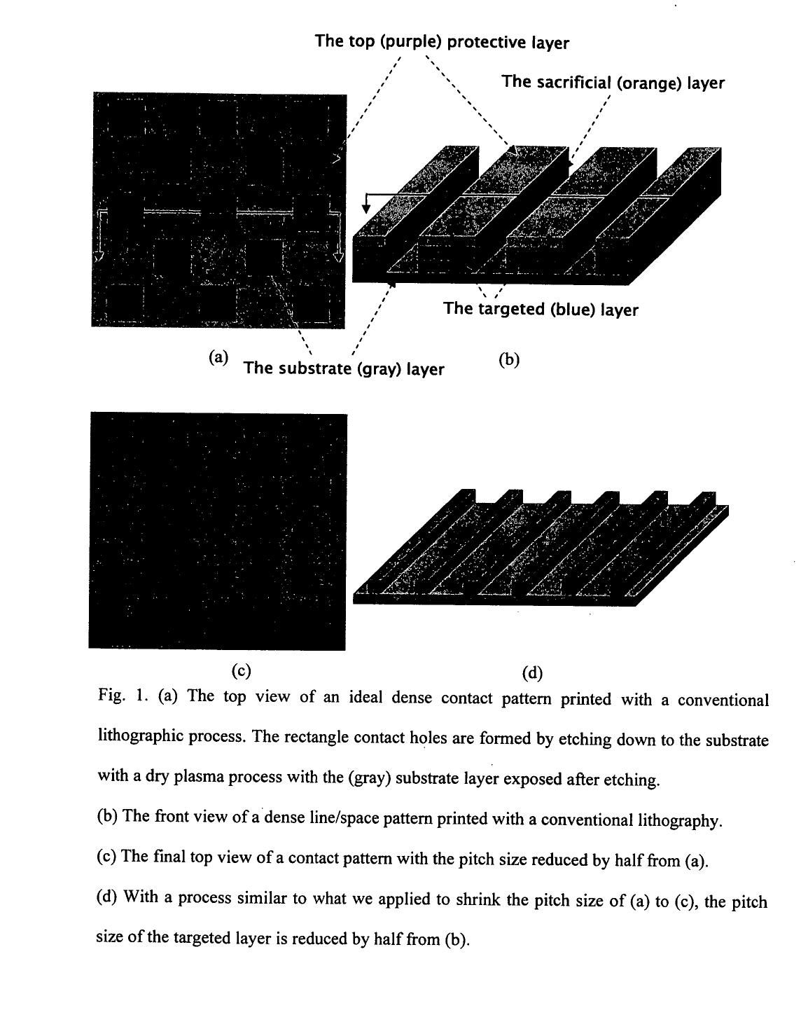

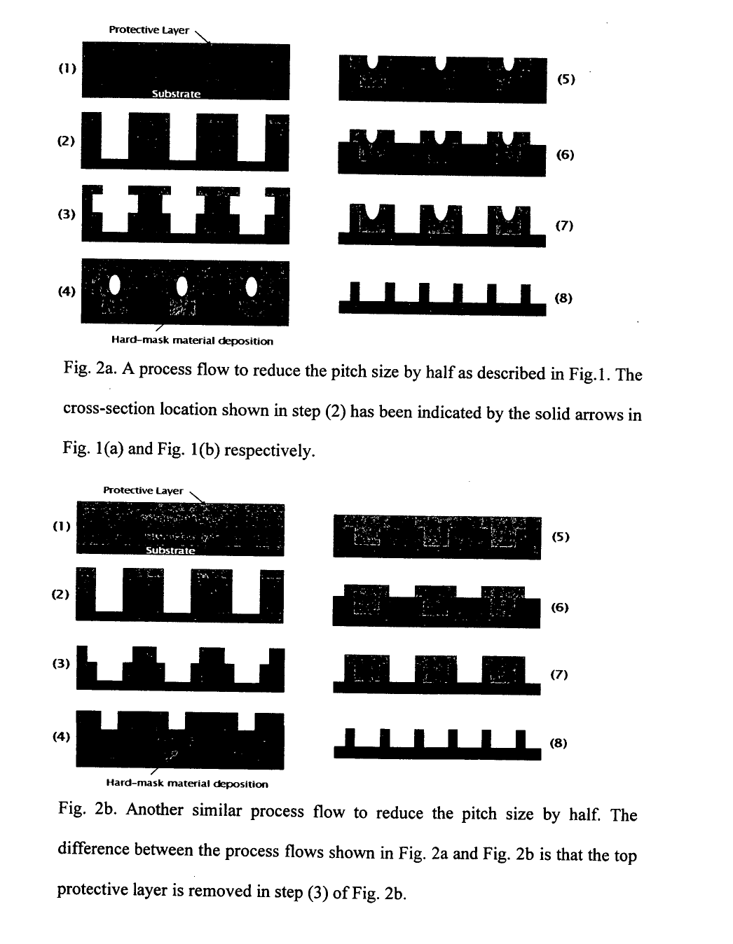

In FIG. 1, we show the top view of dense contact holes (a) and dense line/space (b) patterns printed with a conventional lithographic process. The line/space pattern can be either straight or wiggling, but we only show the straight one in this figure. We shall describe the process flow to reduce the pitch size using the contact pattern as an example, but the same process can also be used for the line/space pattern. First, we assume that pattern (c) has a pitch size (contact's center-to-center distance) smaller than the minimum feature size printable with a lithographic tool in the conventional way. Secondly, pattern (a) has a larger pitch and it can be printed with a conventional lithographic tool. As shown FIG. 2a, we start with a stack of several layers on the wafer and print pattern (a) with a conventional lithography first. Our goal is to develop a non-photolithographic process to double the contact density in the targeted layer as shown in pattern (c). More specifically, we print contact holes of pattern (a) on the resist and transfer the formed resist pattern into the underneath stack layers with an-isotropic plasma etch as shown in the step (2) of FIG. 2a. The protective (top), sacrificial (orange), targeted (blue), and substrate (gray) layers will then be exposed to a chemical solution which will partially etch the sacrificial layer in step (3). It is important that we choose a sacrificial material that can be wet etched with certain highly selective etching solution which will not attack the protective, targeted and substrate layers. Moreover, the chosen chemical solution should allow us to control the wet etch rate accurately such that the remaining (horizontal) width of the sacrificial material will allow us to reduce the pitch size by half later. In general, the remaining width can be controlled by adjusting the etch time in above wet process. After this, a deposition of the hard-mask material will follow. This material will be used as a self-aligned hard mask when we etch the added contact holes into the targeted layer as shown in step (7). It should be kept in mind that the hard-mask material must be resistive to the dry etching of the targeted layer, but not necessary to be the same material as the protective layer (we do not distinguish them in the figure though). After the deposition process filling the trenches, there might be some small cavities formed in the trenches, but they are not harmful to the whole process. Then a CMP (chemical-mechanical polishing) or etch process will be applied to remove the top protective layer and expose the sacrificial layer. The sacrificial material will be released with a wet etch process or be etched away with a highly selective dry etch process. Finally an anisotropic dry etch into the targeted layer and post-etch wet release of the hard-mask material will reduce the pitch size of contact holes by half or double the contact density as shown in the front view of FIG. 2a (8) or the top view of FIG. 1(c).

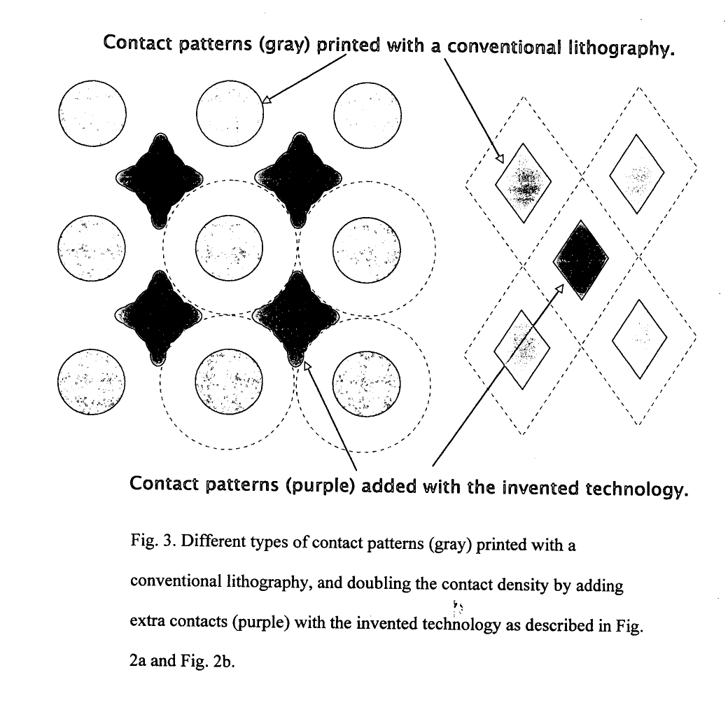

The same process can be applied to the line/space pattern. FIG. 1(b) is the front view of a dense line/space pattern printed with a conventional lithography. With a process similar to what we applied to shrink the pitch size of FIG. 1(a) to FIG. 1(c), the pitch size of the targeted layer shown in FIG. 1(b) can be reduced by half to what we show in FIG. 1(d). Moreover, this technology can be used not only for shrinking the pitch size of the contact pattern shown in FIG. 1(a), but also can be used for many different types of contact patterns such as those shown in FIG. 3.

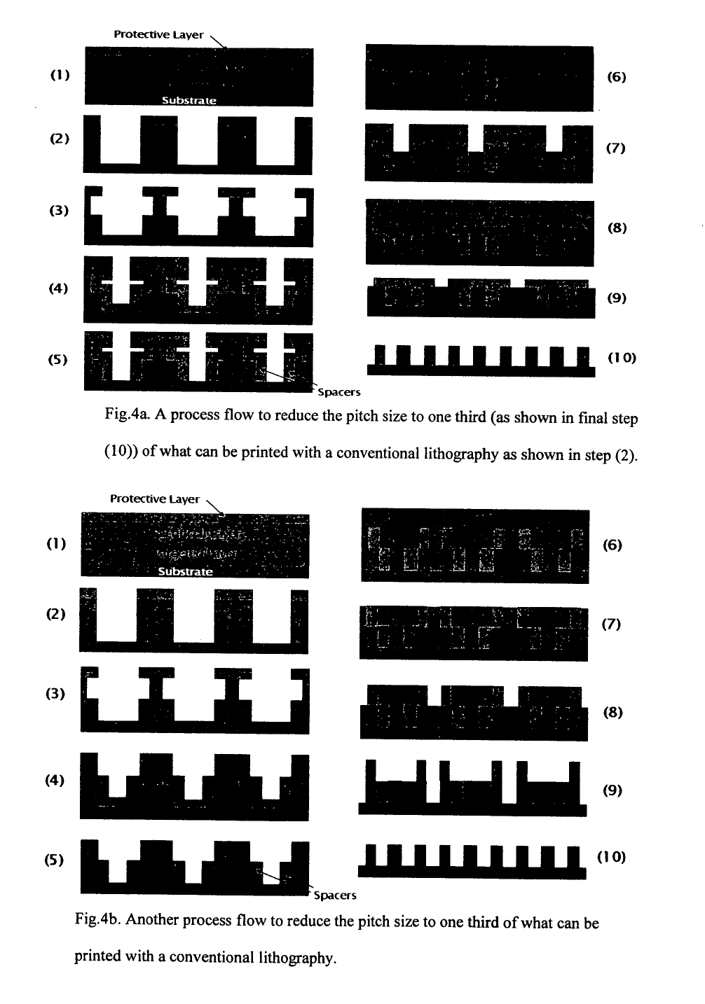

In FIG. 4a, we show a different technology which can be applied to reduce the pitch size of a dense line/space pattern to only one third of the minimum size resolvable with a conventional lithography. The line/space pattern can be either straight or wiggling, but we only show the straight one in this figure. As shown in FIG. 4a, we start with a stack of several layers and then print the line/space pattern on the resist and transfer the formed resist pattern into the underneath stack layers with an-isotropic (dry) plasma etch as shown in the step (2) of FIG. 4a. The protective (top), sacrificial (orange), targeted (blue), and substrate (gray) layers will then be exposed to the chemical solution which will partially etch the sacrificial layer in step (3). It is important that we choose a sacrificial material that can be wet etched with certain highly selective etching solution which will not attack the protective, targeted and substrate layers. Moreover, the chosen chemical solution should allow us to control the etch rate very accurately such that the remaining (horizontal) width of the sacrificial material will be one third of the initial width. In general, the remaining width can be controlled by adjusting the etch time in above wet process. After this, a deposition of the hard-mask material will follow. This material will be used as a self-aligned hard mask when we etch the targeted-layer material as shown in steps (7) and (9). The hard-mask material must be resistive to the dry etching of the targeted layer, but not necessary to be the same material as the protective layer (we do not distinguish them in the figure though). After the deposition process partially filling the trenches as shown in step (4), there might be some small cavities formed, but they are not harmful to the whole process. The following step (5) is a dry etch process which removes the deposited hard-mask material on top of the substrate, and forms some spacers on the sidewalls of the targeted layer. Then a deposition of the targeted-layer material shown in step (6) is used to fill the trenches completely. If the wafer surface after this trench-filling process is not flat, then a CMP process can be applied to flatten the surface. The following step (7) is a (dry) etch back process which makes the top surface of the target material in the trenches at the same level as the top surface of the original target layer. Since the hard-mask material is resistive to the dry etch of the targeted material, the shape of the trenches does not change much. Therefore, we can deposit the hard-mask material to fill the trenches again as shown in step (8). After this, a CMP or etch process is used to partially remove the hard-mask material and expose the sacrificial layer which is then released by a wet etch process or be etched away with a highly selective dry etch process as shown in step (9). Final step (10) is an anisotropic dry etch into the targeted layer followed by post-etch release of the hard-mask material. As a result, we are able to shrink the pitch size down to one third of the initial size of a line/space pattern. Of course, here we see again the importance of choosing a relevant hard-mask material which can be released by certain selective chemical solution (or etched away) without attacking the targeted layer.
What is shown in FIG. 4b is another similar process flow to reduce the pitch size of line/space patterns. The main difference between the process flows described in FIG. 4a and FIG. 4b starts from step (4). In the process shown in FIG. 4b, the top protective layer is removed after step (3). Then a hard-mask layer is deposited and etched back to form spacers as shown in step (5). Again, this hard-mask material does not have to be the same as the top protective layer, but we do not distinguish them in the figure. In step (6), the trenches are filled with a deposition of the targeted-layer material. A following CMP process will flatten the wafer surface and expose the sacrificial material as shown in step (7). The sacrificial material then will be removed as shown in step (8) and the targeted material will be etched as shown in step (9). Finally the hard-mask material is removed leaving a denser line/space pattern as shown in step (10).

### REFERENCES

[1] International Technology Roadmap for Semiconductors (ITRS), 2005 version

1. A sacrificial process that can be used to shrink the pitch size of both line/space (straight or wiggling) and contact-hole patterns by half from the initial pitch size resolvable with a conventional lithography, the process comprising:
a. Starting with a stack of several layers as shown in the step (1) of the attached FIG. 2a, and printing a dense contact-hole pattern or a dense line/space pattern with a conventional lithographic process. The line/space pattern can be either straight or wiggling.
b. Transfer of the formed resist pattern into the underneath stack layers with an-isotropic (dry) plasma etch as shown in step (2) of FIG. 2a.
c. The protective (top), sacrificial (orange), targeted (blue), and substrate (gray) layers (see FIG. 2a) then exposed to a chemical solution which will partially etch the sacrificial layer as shown in step (3). We choose a sacrificial material that can be wet etched with certain highly selective etching solution which will not attack the protective, targeted and substrate layers.
d. Control of the remaining (horizontal) width of the sacrificial material by adjusting the etch time in above wet process as described in c.
e. A following deposition of the hard-mask material. This material will be used as a self-aligned hard mask when we etch the added contact holes into the targeted layer as shown in step (7) of FIG. 2a. The hard-mask material must be resistive to the dry etching of the targeted layer, but not necessary to be the same material as the protective layer (we do not distinguish them in the figure though).
f. A CMP (chemical-mechanical polishing) or etch process applied to remove the top protective layer and expose the sacrificial layer as shown in the step (5) of FIG. 2a.
g. The sacrificial material will be released by a wet etch process or be etched away with a highly selective dry etch process as shown in the step (6) of FIG. 2a.
h. An extra mask can be used to protect the edges of contact array in the following dry etching if needed; otherwise, this step can be skipped.
i. Finally an anisotropic dry etch into the targeted layer and post-etch wet release of the hard-mask material will reduce the size of contact pitch by half or double the contact density, as shown in FIGS. 2a (7) and 2a (8).

2. The process flow shown in FIG. 2b is similar to the method of claim 1 except that the top protective layer is removed in step (3) as shown in FIG. 2b.

3. The method of claims 1 and 2 but starting with different types of contact patterns (as shown in the attached FIG. 3) which are first printed with a conventional lithography.

4. A sacrificial and spacer process (see FIG. 4a) that can be used to shrink the pitch size of a line/space pattern (straight or wiggling) down to one third of the initial pitch size printed with a conventional lithography, the process comprising:
a. Starting with a stack of several layers as shown in step (1) of the attached FIG. 4a and then printing the line/space pattern (with the minimum pitch size resolvable in a conventional lithographic tool) on the resist.
b. Transfer the formed resist pattern into the underneath stack layers with an-isotropic (dry) plasma etch as shown in step (2) of FIG. 4a.
c. The protective (top), targeted (blue), and substrate (gray) layers will then be exposed to the chemical solution which will partially etch the sacrificial layer in step (3). We choose a sacrificial material that can be wet etched with certain highly selective etching solution which, however, will not attack the protective, targeted and substrate layers. The remaining (horizontal) width of the sacrificial material will be one third of the initial width, but it can be arbitrarily controlled by adjusting the wet etch time.
d. A following deposition of the hard-mask material which will be used as a self-aligned hard mask when we etch the targeted-layer material as shown in step (7) of FIG. 4a.
e. The hard-mask material must be resistive to the dry etching of the targeted layer, but not necessary to be the same material as the protective layer (we do not distinguish them in the figure though).
f. The following dry etch process as shown in step (5) of FIG. 4a removing the deposited hard-mask material on top of the substrate, and forming some spacers on the sidewalls of the targeted layer.
g. A following deposition of the targeted-layer material shown in step (6) of FIG. 4a to fill the trenches completely. If the surface is not flat after trench-filling process, a CMP process can be applied to flatten the wafer surface.
h. A dry etch process as shown in step (7) will make the top surface of the target material in the trenches at the same level as the top surface of the original target layer.
i. Deposition of the hard-mask material to fill the trenches again as shown in step (8) of FIG. 4a.
j. A CMP or etch process will partially remove the hard-mask material and expose the sacrificial layer which will then be released with a wet etch process or be etched away with a highly selective dry etch process as shown in step (9) of FIG. 4a.
k. A final anisotropic dry etch into the targeted layer followed by post-etch release of the hard-mask material will reduce the pitch size to one third of the initial pitch size of a line/space pattern.

5. Another sacrificial and spacer process (see FIG. 4b) that can be used to shrink the pitch size of a line/space pattern (straight or wiggling) down to one third of the initial pitch size printed with a conventional lithography, the process comprising:
a. Starting with a stack of several layers as shown in step (1) of the attached FIG. 4b and then printing the line/space pattern (with the minimum pitch size resolvable in a conventional lithographic tool) on the resist.
b. Transfer the formed resist pattern into the underneath stack layers with an-isotropic (dry) plasma etch as shown in step (2) of FIG. 4b.
c. The protective (top), sacrificial (orange), targeted (blue), and substrate (gray) layers will then be exposed to the chemical solution which will partially etch the sacrificial layer in step (3). We choose a sacrificial material that can be wet etched with certain highly selective etching solution which will not attack the protective, targeted and substrate layers. The remaining (horizontal) width of the sacrificial material will be one third of the initial width, but it can be arbitrarily controlled by adjusting the wet etch time.
d. The top protective layer is removed after step (3).
e. Then a hard-mask layer is deposited and etched back to form the spacers as shown in step (5) of FIG. 4b. Again, this hard-mask material does not have to be the same as the top protective layer, but we do not distinguish them in the figure.
f. In step (6), the trenches are filled with a deposition of the targeted-layer material. And a following CMP process will flatten the wafer surface and expose the sacrificial material as shown in step (7).
g. The sacrificial material then can be removed as shown in step (8) and the targeted material will be etched as shown in step (9). If necessary, an extra mask can be used after step (8) to protect the edges of line/space array in the dry etching of step (9); otherwise, this extra-mask step can be skipped (it is not shown in the figure).
h. Finally the hard-mask material is removed leaving the denser line/space pattern as shown in step (10) of FIG. 4b.
